(19) United States
(12) Patent Application Publication
(10) Pub. No.: US 2004/0231990 A1
(43) Pub. Date: Nov. 25, 2004

(54) Electrohydrodynamic microfluidic mixer using transverse electric field

(76) Inventors: Nadine Nina Aubry, Metuchen, NJ (US); John Lyle Batton, Metuchen, NJ (US); Ahmed Ould El Moctar, Nantes cedex (FR)

Correspondence Address: MOSER, PATTERSON & SHERIDAN L.L.P., 595 SHREWSBURY AVE, STE 100, FIRST FLOOR, SHREWSBURY, NJ, 07702, US

(21) Appl. No.: 10/850,913

(22) Filed: May 20, 2004

Related U.S. Application Data
(60) Provisional application No. 60/472,573, filed on May 22, 2003.

(51) Int. Cl. H01L 29/76; H01L 31/062

(52) U.S. Cl. 204/547; 204/451

(57) ABSTRACT

Simplicity of design is achieved for an electrohydrodynamic microfluidic mixer by applying an electric field substantially transverse to the flow direction and substantially orthogonal or normal to the interfacial plane between the fluids being mixed in the main channel. The electric field is wide enough to encompass substantially the entire depth of the main channel in the microfluidic mixer. In one exemplary embodiment, the electrohydrodynamic microfluidic mixer comprises a substrate, one main channel disposed on the substrate, first and second inlet channels disposed on the substrate and individually coupled to the main channel, and first and second electrodes disposed on opposite sides of the main channel for applying an electric field across the main channel substantially transverse to the flow direction in the main channel. Field uniformity across the desired cross-section of the main channel is achieved by having the electrode thickness be substantially equal to the main channel depth. Disposition of the electrodes is judiciously controlled to generate the electric field in a direction substantially orthogonal or normal to the interfacial plane between the fluids in the main channel.

### CROSS-REFERENCE TO RELATED APPLICATIONS

This application claims benefit of U.S. provisional patent application Ser. No. 60/472,573, filed May 22, 2003, which is herein incorporated by reference in its entirety.

### BACKGROUND OF THE INVENTION

1. Field of the Invention

This invention relates to the field of microchannel devices and, more particularly, to such active devices that perform microfluidic mixing of two or more fluids flowing in the microchannel by using an applied electric field.

2. Description of the Related Art

Fluid mixing in microchannels is needed for many applications ranging from miniaturized analytical and synthetic chemistry to DNA microarray technology to the transport of small quantities of dangerous or expensive materials. But mixing in microchannels is typically difficult to achieve because of the miniature scale involved.

Fluid flows in micron-scale straight channels having smooth walls are laminar and uniaxial and occur at low Reynolds numbers. Mixing in these channels usually occurs by molecular diffusion in the substantial absence of turbulence. Diffusive mixing has been found to be a relatively slow process that relies on a prohibitively long channel to accomplish the mixing. In practice and in keeping with microminiaturization, it has been necessary to fabricate new devices that accelerate the mixing process in relatively short channels.

Some new devices rely on active processes where energy is injected into the fluid flow. Many devices have been realized or suggested by miniaturizing macroscale devices. Of these devices, certain active devices involve moving parts that are not amenable to replication at the miniature scale on the order of microns. Of the remaining devices, many involve the introduction of energy through the application of an external field to the flow in the main channel of the device. These active microfluidic mixers utilize externally applied fields such as ultrasonics, electroosmosis, dielectrophoresis, electrowetting, magnetohydrodynamics, and electrohydrodynamics.

Electrohydrodynamic microfluidic devices accomplish mixing in certain cases by using an electric field to pulse the cross flows of liquids into the main channel or to generate convection flow by inducing a shear force transverse to the flow direction. In the latter case, the electrodes used to apply the field that induces the shear force necessary for convection to occur must be carefully aligned with respect to an interfacial plane between the fluids being mixed. Alignment must be carried out in such a way that the resulting electric force profile is offset by a small angle from being parallel to the interfacial plane. Usually this requires that one electrode be positioned on one side of the plane while the other electrode is positioned on the other side of the plane on the opposite side of the main channel. This approach presents added complexity for the fabrication of such microfluidic mixers.

### SUMMARY OF THE INVENTION

Simplicity of design is achieved in accordance with the principles of the present invention for an electrohydrodynamic microfluidic mixer by applying an electric field substantially transverse to the flow direction and substantially orthogonal or normal to the interfacial plane between the fluids being mixed in the main channel. The electric field is wide enough to encompass substantially the entire depth of the main channel in the microfluidic mixer.

In one exemplary embodiment, the electrohydrodynamic microfluidic mixer comprises a substrate, one main channel disposed on the substrate, first and second inlet channels disposed on the substrate and individually coupled to the main channel, and first and second electrodes disposed on opposite sides of the main channel for applying an electric field across the main channel with a component transverse to the flow direction in the main channel. Field uniformity across the desired cross-section of the main channel is achieved by having the electrode thickness be substantially equal to the main channel depth. Disposition of the electrodes is judiciously controlled to generate the electric field with a component in a direction orthogonal or normal to the interfacial plane in the main channel.

In another exemplary embodiment, multiple electrode pairs are disposed at separate locations along the main channel to permit application of multiple transverse electric fields to the mixer. All the electric fields are preferably substantially uniform across the desired cross-sections of the main channel and all the fields are generated such that they exhibit a non-zero component in a direction orthogonal or normal to the interfacial plane in the main channel. In this embodiment, the multiple pairs of electrodes can be automatically switched or programmably selected to mix a wide range of fluids flowing at a wide range of velocities.

In the exemplary embodiments described herein, the use of direct current and alternating current fields is contemplated.

### BRIEF DESCRIPTION OF THE DRAWINGS

A more complete understanding of the invention may be obtained by reading the following description of specific illustrative embodiments of the invention in conjunction with the appended drawings in which:

FIG. 1 shows a simplified schematic drawing in partial cutaway view of an electrohydrodynamic microfluidic mixer realized in accordance with the principles of the present invention;

FIGS. 2A, 2B, and 2C show comparative plots of electrical properties for exemplary doped and undoped fluids utilized in the operation of the mixer in FIG. 1;

FIGS. 3a, 3b, and 3c show photographically the successive stages of operation of the mixer in FIG. 1 when a DC electric field is applied;

FIG. 4 show a graph depicting the variation of mixing index of the fluids versus DC electric field intensity;

FIGS. 5a-5e show photographically the successive stages of operation of the mixer in FIG. 1 when an AC electric field is applied;

FIG. 6 show a graph depicting the variation of mixing index of the fluids versus AC electric field intensity;

FIG. 7 show photographically a particular stage of mixing during operation of the mixer in FIG. 1 when an AC electric field is applied;

FIG. 8 shows a comparison between the variation of the mixing index and the frequency of the electric field for square wave and sinusoidal fields; and

FIG. 9 shows photographically successive stages of mixing during operation of the mixer in FIG. 1 when an AC electric field is applied at multiple electrode positions along the main channel of the mixer.

It is to be noted that the appended drawings illustrate only typical embodiments of this invention and are therefore not to be considered limiting of its scope, for the invention may admit to other equally effective embodiments. Where possible, identical reference numerals have been inserted in the figures to denote identical elements.

### DETAILED DESCRIPTION

In the following description, we will explain details about an active microfluidic mixer based on both an electric force generated in presence of an applied transverse electric field and nonuniformities in predetermined electrical properties of the fluids. In particular, two fluids with identical mechanical properties and different conductivity and permittivity are used in the mixer. In the absence of an electric field, mixing is very poor and the two fluids meet only in the mid-plane at a flat interface. When the electrodes are energized by the applied field, the field creates a strong force substantially perpendicular (normal) to the interface causing the two fluids to intermingle and therefore enhancing mixing between the two fluids. In the embodiments described herein where the fluids flowed at a volume flow rate of 0.26 ml/s (corresponding to a Reynolds number less than 0.02) in a microchannel of cross-section 250 μm×250 μm, the fluids were mixed quasi-instantaneously (in less than 0.1 s) and over a very short distance (fraction of the electrodes width of 250 μm). The applied electric field is continuous (DC) or alternating (AC).

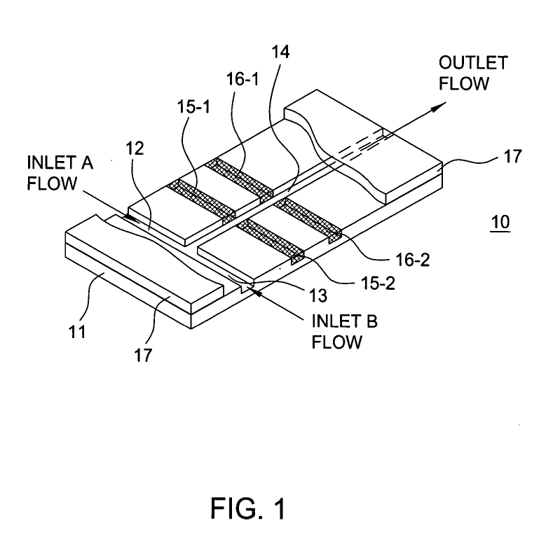

FIG. 1 shows a simplified schematic drawing in partial cutaway view of an electrohydrodynamic microfluidic mixer realized in accordance with the principles of the present invention. The mixer and its component parts are not drawn to scale. Mixer 10 includes substrate 11, cover plate 17, inlet channels 12 and 13, main channel 14, first electrode pair including electrodes 15-1 and 15-2, and second electrode pair including electrodes 16-1 and 16-2. Although the exemplary embodiment shown in FIG. 1 includes two pairs of electrodes, it is contemplated that one or more pairs of electrodes can be fabricated to realize the mixing device in accordance with the principles of the present invention. It will be appreciated by persons skilled in the art that a mixing device having multiple pairs of electrodes can be utilized in modes where any number of electrode pairs can be energized to accomplish a desired type of mixing without departing from the spirit and scope of the present invention. It will also be appreciated that the configuration of the inlet and main channels can be varied from the T configuration shown in FIG. 1 to a Y configuration or any other desirable inlet-main channel configuration including offset inlet channels. Furthermore, it will be appreciated by persons skilled in the art that the present invention is adaptable to channel configurations featuring more than two inlet channels.

The flow configuration is shown in FIG. 1 as depicted by the directional arrows labeled “inlet A flow” in inlet channel 12, “inlet B flow” in inlet channel 13, and “outlet flow” in main channel 14. Hereinafter, the downstream direction in main channel 14 is also referenced as the x-direction, the direction normal to the initial interface between the two fluids (that is, parallel to an electrode pair) is the y-direction, and the remaining direction along the depth of main channel 14 normal to the plane of the substrate is the z-direction.

In the exemplary embodiment shown in FIG. 1, the microchannel has a T-shape with two inlet channels 12 and 13 forming the halves of the cross-bar and with main channel 14 (the outlet channel) oriented perpendicular to the inlet channels. Main channel 14 is the channel in which mixing of the fluids takes place. This channel is equipped with sets of electrodes mounted in the channel walls along the y-direction. Electrodes within a pair are disposed on opposite walls of the main channel and face each other so that the electric field can be applied across the main channel in the y-direction. The electric field applied by the electrodes is transverse to the flow direction and substantially normal to the interface layer formed between the two fluids. In experimental practice, it is desirable to simplify the operation of the electrodes by grounding one electrode of a pair and energizing the other electrode in the same pair.

Mixer 10 was made using conventional machining practices. A 3.175 mm thick piece of Lexan material was used for the channel walls. In order to hold the piece immobile and flat for machining, it was glued to a rigid substrate (not shown in the figures) using double sided grinding tape. Wire electrode slots were made first using a 0.25 mm jeweler saw blade. The saw speed and feed rate were adjusted to provide clean material cutting and prevent the Lexan material from melting. Titanium wires having a 0.25 mm diameter were then press fitted into the wire electrode slots to from each of electrodes 15-1, 15-2, 16-1, and 16-2. A layer of epoxy was used to glue and seal the titanium electrode wires into the electrode slots. After curing the epoxy glue for the electrodes, main flow channel 14 and inlet channels 12 and 13 were milled using a 0.25 mm diameter carbide endmill. The feed rate and endmill rotation speed were adjusted to provide clean cutting without melting the Lexan. Main flow channel 14 was made by machining the Lexan and through electrode wires in the main channel. A microscope glass coverslip was employed for cover plate 17. The coverslip was glued on top of the device to seal the microchannel and allow the visualization of the flow through the channel wall. Although the exemplary device shown in FIG. 1 was fabricated with Lexan and titanium wires, it is contemplated that other microfluidic mixing devices can be realized using materials such as etched glass, silicon, and imprinted plastics.

In the exemplary embodiment shown in FIG. 1, the main channel 14 where the fluids are mixed is 30 mm long, 250 μm wide and 250 μm deep. These dimensions translate into a hydraulic diameter l=2.5×10⁻⁴ m. The series of wire electrode pairs placed in the direction perpendicular to the main channel are formed within electrode slots measuring 250 μm wide and 250 μm deep per electrode section. The electrode pairs are preferably spaced apart by 500 μm along the x-direction. The electrodes are energized by a signal generator and amplifier for the alternating voltage case, and by a DC power supply for the continuous voltage case. Neither the signal generator nor the amplifier nor the DC power supply are shown in the FIGs.

For better control and visualization of the experimental results and in order to avoid pulsing perturbations in the channel flows, it was determined that gravity action would be used to create the flow rather than pumps such as a syringe peristaltic pump. In practical applications, however, it is contemplated that conventional microfluidic pumps such as positive pressure pumps and electroosmotic pumps can also be used to realize the present invention.

In order to utilize gravity action to create the flow for the device experiments, the fluids to be supplied to the inlet channels are each held in reservoirs at a height above the microfluidic mixing device. After the fluids traverse the main channel, the fluid mixture is evacuated at the far end of the main channel. The fluids can be collected in a container or flowed to another device. The average velocity of each fluid is 2.1 mm/sec in the inlet channel prior to reaching the confluence and 4.2 mm/sec in the main channel. The confluence region is defined generally by the intersection of the inlet channels and the main channel.

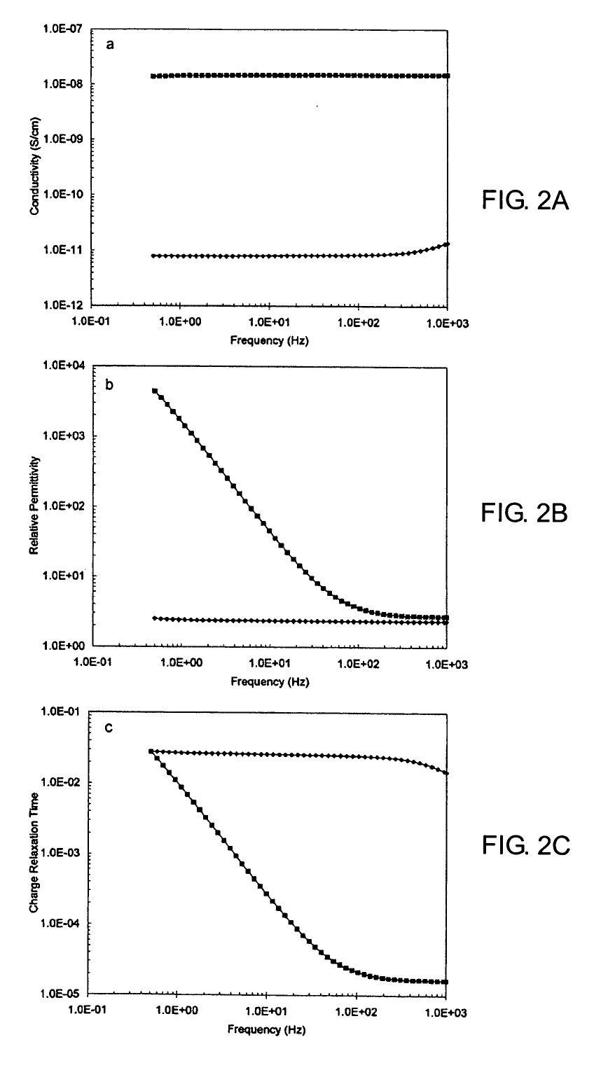

Microfluidic mixing device 10 is designed to mix fluids having different electrical properties as described in more detail below. In general, the fluids have a difference in permittivity or conductivity or both. For the experimental results described herein, the chosen fluids were selected from simple, commercially available fluids having properties that would readily demonstrate the features of the present invention. One of the fluids selected for experimental use was pure Mazola corn oil. The other fluid selected was the same corn oil colored with a commercial oil-based Teal dye and doped with oil-miscible antistatic Stadis® 450 to increase its electrical conductivity and permittivity. The density and viscosity of the fluids are r=0.992×10³ kg·m⁻³ and h=6×10⁻² kg·m⁻¹·s⁻¹, respectively. These characteristics create a Reynolds number of Re=0.0174. The electrical characteristics of the fluids are compared in the graphs shown in FIG. 2.

FIG. 2A shows the conductivity of the experimental fluids; FIG. 2B shows the permittivity of the fluids; and FIG. 2C shows the charge relaxation time at the fluid interface for the fluids. All these graphs show measurements as a function of frequency. The results for the undoped fluid are shown with diamonds at each point, whereas the results for the doped fluid are shown with squares at each point. Permittivity is normalized by the permittivity of a vacuum, that is, ε₀=0.088542 farad/m, to produce a relative permittivity. From FIG. 2A, it is apparent that the difference in conductivity between the two fluids is significant (three orders of magnitude) at all frequencies shown. From FIG. 2B, it is apparent that the difference in permittivity is significant at low frequencies (three orders of magnitude), but decreases with increasing frequency to nearly zero at f˜100 Hz.

Charge relaxation time τ at the interface between the two fluids is determined by the ratio of the fluid permittivity ε and the fluid conductivity σ, wherein τ=ε/σ. The charge relaxation time measures the rate at which free charges relax from the bulk of the fluid to the outer boundaries of a dielectric mass. Free charge relaxation time τ is approximately 3.6×10⁻⁶ s for distilled water and 0.68 s for corn oil. For a discontinuous interface between the two layers of fluid denoted by the subscripts a and b corresponding to the inlet channel flows shown in FIG. 1, the charge relaxation time of unpaired surface charge density at the fluid interface in response to a step in voltage is given by the formula:

$$τ = \frac{{ϵ}_{a} + {ϵ}_{b}}{{σ}_{a} + {σ}_{b}} .$$

FIG. 2C demonstrates that the charge relaxation time computed using the formula above, where subscripts a and b refer to the two fluids used in our experiments, decreases drastically as the AC electric field frequency increases. This has the effect of decreasing the electric Reynolds number

$$( {Re}_{elec} = \frac{τ}{\frac{l}{U}} ) ,$$

which varies from being on the order of 10⁻¹ at 0.5 Hz, to 10⁻³ at 10 Hz, and to 10₋₄ at 100 Hz. These small numbers justify the assumption that the relaxation of the free charges at the fluid interface is quasi-instantaneous. Another consequence of the decrease of τ is a reduction in the intensity of the electrophoretic force component proportional to the conductivity gradient.

Transparent microchannel device 10 is placed horizontally under the lens of a microscope to visualize the mixing during the experiments and to capture the mixing process photographically for the FIGs. herein. A digital video camera mounted on the microscope records instantaneous images of the flow in the x-y plane. The camera is focused at approximately the middle depth of the main channel. Instantaneous images are then extracted and analyzed on a PC based on the grey scale levels, the area of analysis being an x-y rectangle located just downstream from the energized electrodes. For the photographs shown in the FIGs., the width of the rectangle coincides substantially with the channel width and the length of the rectangle begins at the upstream corners of the first pair of electrodes and covers approximately 500 μm (about two channel depths) along the direction of flow. Four photographic images for each condition, taken at quarter cycles and including the maximum and minimum electrical fields, were used in the case of an AC field. For more precision, five DC field images were considered in the analysis.

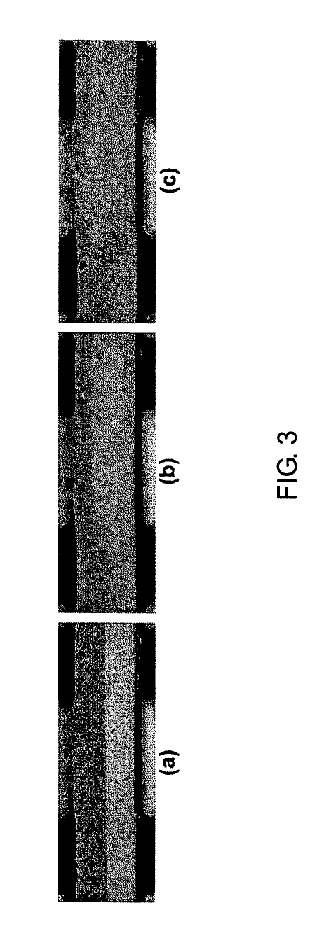

FIGS. 3a, b, and c are photographs of the microfluidic mixer in operation. These photographs show stages of the mixing process of both fluids in main channel 14. FIG. 3a is a photograph displaying the initial condition with no applied electric field. Both fluids are shown flowing (the x-direction is from left to right in each photograph) in their respective portions of the main channel. It is clear that initially the flow is very laminar and stable, with the two fluids clearly separated.

A hydrodynamic instability is observed in FIG. 3b with an applied electric field intensity of E˜4×10⁵ V/m (voltage of 100 V). Mixing is observed commencing in FIG. 3b as compared with the unmixed state of FIG. 3a. It is apparent that, under the electric field conditions described above, there is still a layer of each fluid near the outermost portions of the channel where the fluid is substantially unmixed.

For an applied DC field, the instability is detected at an electric field intensity of E˜2×10⁵ V/m (voltage of 50 V). The threshold for this instability depends on the perturbation of the interface between the two fluids and on the shock introduced by the initial application of the electric field. It has been observed in these experiments that, if the application of the electric field is gradual, onset of the instability is delayed. A hysteretic effect has also been observed in the sense that a gradual decrease of the field keeps the deformed interface below the instability threshold value. Mixing is observed to take place quasi-instantaneously (less than 0.1 s) and over a very short distance (fraction of the electrode width) as the electric field is turned on, and disappears also quasi-instantaneously as the electric field is turned off.

Once the instability is triggered in the main channel, it affects the channel flow to various degrees depending on the applied potential difference or field strength. In particular, the width of the affected mixing zone around the mid-plane initial interface can vary.

As shown in FIG. 3c, even better mixing is achieved throughout the width of the channel with an applied transverse electric field of intensity E=6×10⁵ V/m (a voltage of 150 V). Mixing thus improves with increasing potential difference, and therefore with increasing electric field strength. There is a saturation effect observed after maximal mixing is reached.

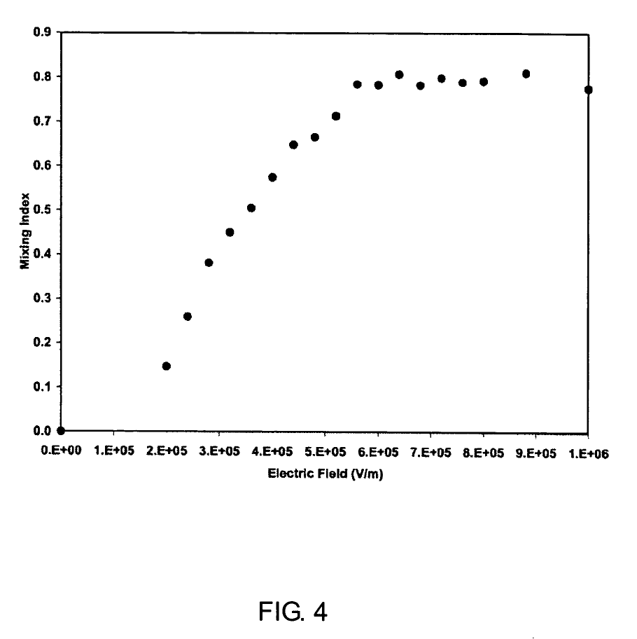

Dependence of the mixing upon the electric field intensity is quantified in FIG. 4 where the degree of mixing is plotted against the electric field strength. A reversal of the potential, which changes the sign of the electric field, is observed not to affect the results. The mixing parameter is based on the coefficient of variation, CV, of grey scale levels in the photograph. CV is determined by dividing the standard deviation by the mean grey scale level. Light grey corresponded to the pure undoped fluid, and dark grey referred to the doped and dyed fluid. Comparing the CV of images obtained with the applied electric field with the CV of images obtained with no applied electric field yields information about the mixing due to the electric field. However, since the background image does not have a negligible CV, we subtract its CV from the other CVs. The extent of mixing is thus determined using the following equation:

$$Mixing = 1 - \frac{{CV}_{elect} - {CV}_{bkgnd}}{{CV}_{nofield} - {CV}_{bkgnd}} ,$$

where CV_{elect} is the CV obtained from the images obtained with the applied electrical field, CV_{bkgnd} is the CV of the background image, and CV_{nofield} is the CV obtained from the images obtained without electrical field. The subtraction from 1 is used so that the mixing index is theoretically zero in the case of no mixing, and 1 in the case of perfect mixing.

In experimental practice, the transverse DC electric field was replaced by a transverse AC electric field. In the AC field, the applied current oscillates at the frequency f, which is variable in order to study its role on the mixing efficiency. From a practical viewpoint, an AC electric field is sometimes advantageous over a DC field as it can prevent the occurrence of electrolysis. Although many different frequencies are applicable to the microfluidic mixer, the AC fields of interest were chosen to have frequencies of 0.5 Hz, 10 Hz and 100 Hz.

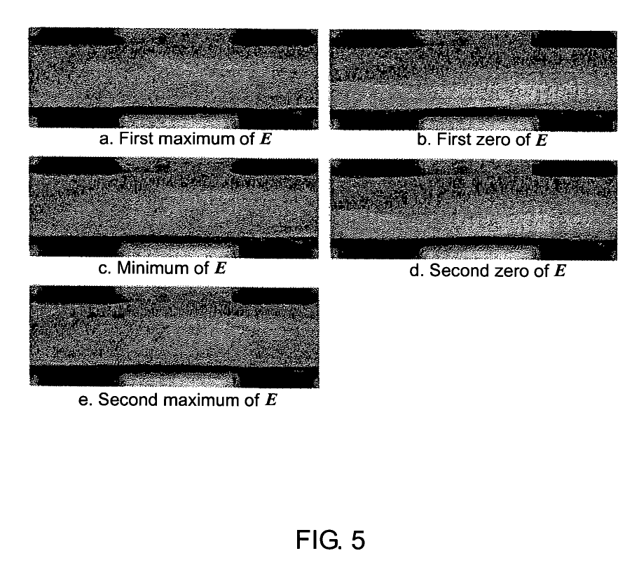

FIG. 5 shows photographs of different stages of the mixing process in the main channel for the two fluids through one complete AC cycle. The mixing operation was observed at the maxima, minima, and zero crossings for the field. It has been determined that, as in the case of the DC field (continuous current), the extent of the mixing varies with the electric field intensity. This means that mixing varies during a cycle of the electric field. In FIG. 5, the flow subjected to a 0.5 Hz transverse electric field Eₘₛ=4.24×10⁵ V/m−voltage of 300 V peak to peak, the maximum of this AC electric field being equivalent to a DC electric field of 6×10⁵ V/m in intensity. As shown in FIG. 5, the mixing process in the main channel is visualized during a complete period of the electric field, particularly when the electric field strength is at its maximum (FIG. 5a), goes through zero (FIG. 5b), reaches a minimum (FIG. 5c), goes through zero again (FIG. 5d), and returns to its maximum (FIG. 5e). The effect of the electric force on mixing is maximum when the electric field is itself at either extreme, maximum (FIGS. 5a & e) and minimum (FIG. 5c). In addition, the effect of the electric force on mixing almost disappears when the electric field goes through zero (FIGS. 5b & d).

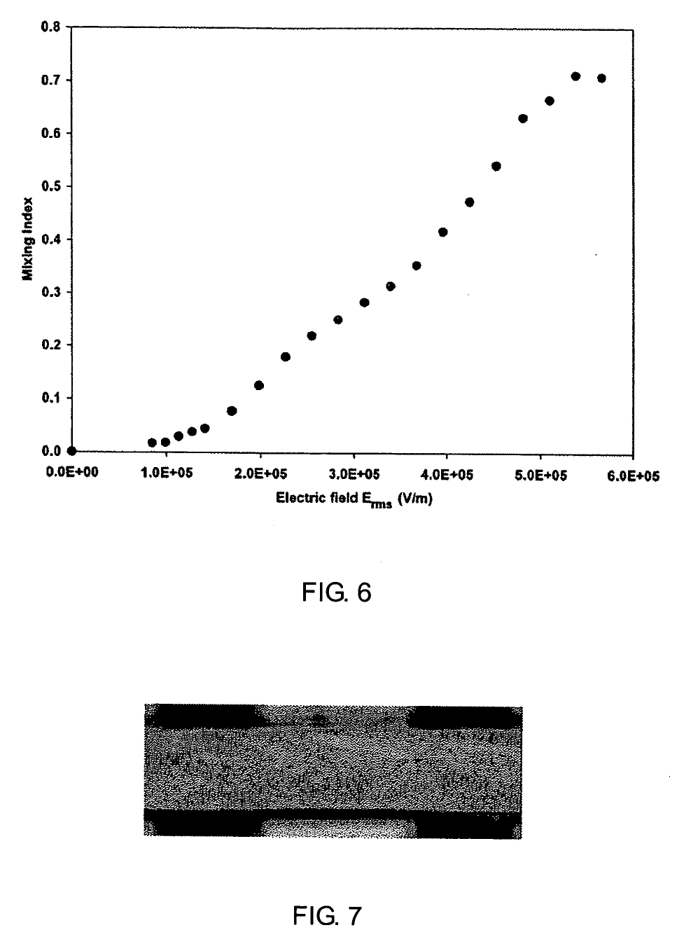

Intensity of the AC field is also important to the mixing operation. Dependence of the mixing index on the intensity of the AC electric field is shown in FIG. 6. FIG. 6 demonstrates quantitatively that the mixing index increases as a function of AC electric field intensity.

In presence of an AC field, the flow shown in FIG. 7 reveals a pulse corresponding to the time at which the electric field passes through its maximal value at the instability threshold. The AC field in this case is a square wave similar is properties to the sinusoidal field used in FIG. 5. This pulse in the flow is more or less elongated, depending on the frequency of the electric field. The pulse is followed by a fluid zone for which the interface between the two fluids is insubstantially deformed. This behavior produces a succession of mixed and unmixed zones in the downstream direction. The extent of these zones depends on whether the flow has the time to fully develop between two adjacent pulses. This phenomenon can be understood in terms of Strouhal and Stokes numbers.

For the considered flow rate and frequency of 0.5 Hz, the Strouhal and Stokes numbers take the values St˜0.03 and Sto˜0.0005, respectively. For this relatively small frequency of the electric field, the Stokes number is small and the flow has the time to fully develop in between the pulses. In contrast, at a relatively high frequency value of 100 Hz, for example, these two parameters are St˜6 and Sto=0.1. As these parameters increase, the quality of the mixing process in the main channel decreases. At high frequencies, the gradient of permittivity becomes very low and the conductivity gradient decreases tremendously as the electric frequency increases. Both of these effects also undermine the mixing capability of the microfluidic mixer. It is therefore desirable to operate the mixer at low Stokes number values to create a sufficiently large electric force, as well as to allow the fluid flow to fully develop in between the electrical pulses.

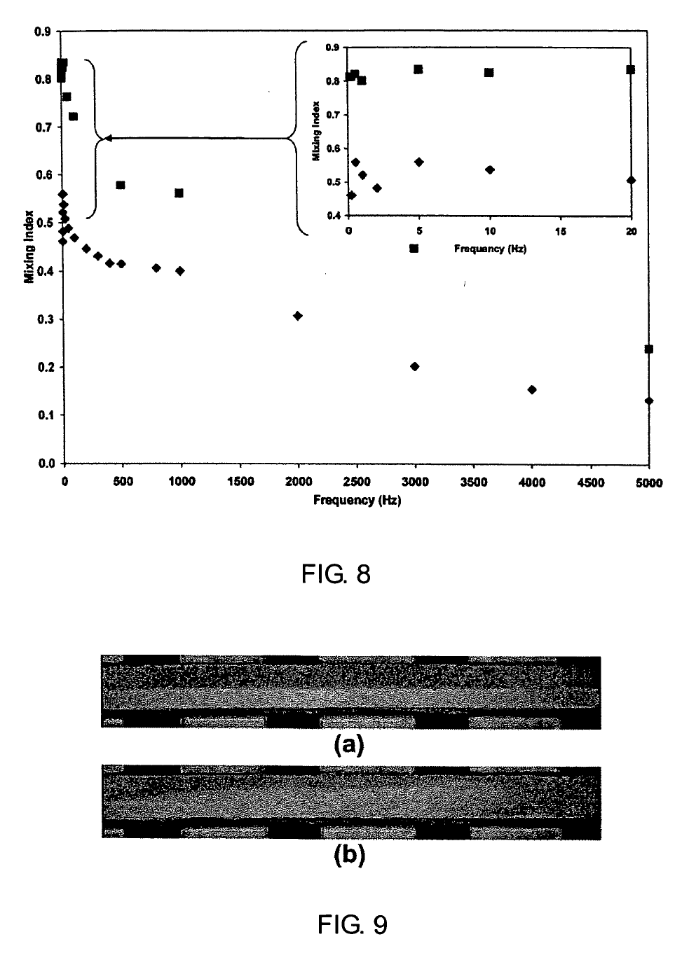

FIG. 8 shows the evolution of the mixing index as a function of frequency for an electric field of 4.24×10⁵ V/m. A sinusoidal AC electric field is used for the values shown as diamonds, whereas a square AC electric field is used for the values shown as squares. It is clear that for frequencies higher than 1 Hz or so, the mixing efficiency decreases monotonically.

In an attempt to keep the electric force intensity at its maximum value as long as possible, it is contemplated that a square alternating current field is desirable. That is, one should use a field that oscillates between a positive and a negative value by means of a step function. This contrasts with the sinusoidal electric field where the oscillation takes place between the two optimal values in a gradual manner. From experimental practice, it has been observed that better mixing results are obtained for a square AC field.

FIG. 7 shows the mixing state generated by such an electric field using the same intensity and frequency (Eₘₛ=4.24×10⁵ V/m, f=0.5 Hz) as for the case shown in FIG. 5. A comparison between FIG. 7 and FIGS. 5a-e in an average sense shows the superiority of the results obtained with the square electric field. In addition, the use of such a square AC field allows mixing to be maintained at a high index level up to relatively high frequencies compared with the previous case. This is demonstrated in FIG. 8 where the mixing index averaged per cycle is plotted using squares against the frequency of the electric field for an AC square electric field of intensity Eₘₛ=4.24×10⁵ V/m. The comparison of the two curves in FIG. 8 shows that the square field is superior to the sinusoidal one in terms of mixing efficiency. This superiority would be accentuated in a comparison with the average mixing index obtained in the sinusoidal case.

All the experimental tests described above have been performed with only one energized pair of electrodes such as electrodes 15-1 and 15-2. Tests have also been conducted using two pairs of electrodes. The use of multiple electrode pairs improves the quality of the mixing process. By using multiple pairs of electrodes, it is also possible to decrease the intensity of the electric field at each downstream while still being able to obtain a similar mixing result.

The results for such an embodiment of the mixer are shown in FIG. 9. In FIG. 9, mixing is viewed over a distance covering four pairs of electrodes. After energizing each of the first three pairs of electrodes with an electric field of intensity Eₘₛ=2.834×10⁵ V/m, it is observed that mixing develops as the flow travels downstream with significant improvements as the flow passes each electrode pair. As the fluid passes the third pair of electrodes, mixing is substantially as complete as it was by using one pair of electrodes with an electric field of much higher intensity (Eₘₛ=4.24×10⁵ V/m).

The present invention has also been tested using fluids such as deionized water and the same fluid dyed and doped with table salt. Such experimental results have shown that the inventive electrohydrodynamic mixer presented here is applicable to aqueous solutions.

While the foregoing is directed to embodiments of the present invention, other and further embodiments of the invention may be devised without departing from the basic scope thereof, and the scope thereof is determined by the claims that follow. In particular, it is contemplated that the electrodes within a pair can be offset from one another on opposite sides of the main channel rather than being exactly opposite each other. Such an offset still results in a field that has components that are substantially transverse to the flow direction and substantially normal to the interface layer between the fluids. In addition, it is contemplated that elongated electrodes can yield high mixing efficiencies. The elongated electrodes extend for a distance along each wall of the main channel. Elongated electrodes within a pair are opposite each other along the main channel.

1. A microfluidic mixing device comprising:
a substrate;
at least a first main channel disposed on said substrate;
at least first and second inlet channels disposed on said substrate and individually coupled to the at least first main channel, said first inlet channel for supplying a first fluid to the main channel and said second inlet channel for supplying a second fluid to the main channel, said first and second fluids forming an interface layer therebetween in said main channel; and
at least a first pair of electrodes, each pair of electrodes including first and second electrodes, said first and second electrodes being disposed on opposing sides of said main channel to apply a transverse electric field across the main channel through a portion of the interface layer, said electrodes capable of applying the electric field substantially normal to said portion of the interface layer.

2. The microfluidic mixing device as defined in claim 1 wherein the first and second electrodes in each pair of electrodes are each coextensive with a transverse dimension of the main channel.

3. The microfluidic mixing device as defined in claim 2 wherein the electric field is a direct current field.

4. The microfluidic mixing device as defined in claim 2 wherein the electric field is an alternating current field.

5. The microfluidic mixing device as defined in claim 1 including at least a second pair of electrodes, said second pair of electrodes including first and second electrodes, said first and second electrodes of said second pair being spaced apart from said electrodes of said first pair of electrodes and being disposed on opposing sides of said main channel to apply a transverse electric field across the main channel through a second portion of the interface layer, said electrodes capable of applying the electric field substantially normal to said second portion of the interface layer.

6. The microfluidic mixing device as defined in claim 6 wherein the first and second electrodes in the at least first and second pairs of electrodes are each coextensive with a transverse dimension of the main channel.

7. The microfluidic mixing device as defined in claim 6 wherein the electric field applied by one of said pairs of electrodes is a direct current field.

8. The microfluidic mixing device as defined in claim 6 wherein the electric field applied by one of said pairs of electrodes is an alternating current field.

9. A method for mixing fluids in a microfluidic mixing device including a main channel for supporting a flow of at least first and second fluids, said first and second fluids having different electrical characteristics, the method comprising the steps of:
injecting first and second fluids into the main channel so that an interface layer is formed between the first and second fluids in the main channel; and
applying an electric field at at least a first position along the main channel in a direction that is substantially transverse to a direction of fluid flow in the main channel, said electric field also being applied in a direction that is substantially normal to the interface layer, and said electric field being sufficient to induce a mixing action between the first and second fluids.

10. The method as defined in claim 9 the electric field is a direct current field.

11. The method as defined in claim 9 wherein the electric field is an alternating current field.

12. The method as defined in claim 9 further including the step of applying an electric field at at least a second position along the main channel in a direction that is substantially transverse to a direction of fluid flow in the main channel, said second position being separate from said first position, and said electric field at said second position also being applied in a direction that is substantially normal to the interface layer, and said electric field at said second position being sufficient to induce additional mixing action between the first and second fluids.

13. The method as defined in claim 12 the electric field is a direct current field.

14. The method as defined in claim 12 wherein the electric field is an alternating current field.
